(19) United States
(12) Patent Application Publication
(10) Pub. No.: US 2015/0334869 A1
(43) Pub. Date: Nov. 19, 2015

(54) FREQUENCY UP CONVERTER HAVING COMPACT SIZE AND ENHANCED HEAT EMISSION CHARACTERISTICS

(71) Applicant: XMW INC., Deajeon (KR)

(72) Inventor: Moo Hong LEE, Daejeon (KR)

(21) Appl. No.: 14/517,988

(22) Filed: Oct. 20, 2014

(30) Foreign Application Priority Data
May 15, 2014 (KR) 10-2014-0058598

(51) Int. Cl. H05K 7/20; H05K 1/18; H05K 5/03

(52) U.S. Cl. CPC H05K 7/205; H05K 5/03; H05K 1/181

(57) ABSTRACT

A frequency up converter having a compact size and enhanced heat emission characteristics by improving an arrangement structure of circuit boards is provided. The frequency up converter can enhance the heat emission characteristics and also reduce an entire volume and weight by classifying the devices according to their heat emission characteristics, separately arranging boards in a multi-step structure, and installing a heat sink.

### CROSS-REFERENCE TO RELATED APPLICATION

This application claims priority to and the benefit of Korean Patent Application No. 2014-0058598, filed on May 15, 2014, the disclosure of which is incorporated herein by reference in its entirety.

### BACKGROUND

1. Field of the Invention

The present invention relates to a frequency up converter, and more particularly, to a frequency up converter capable of enhancing heat emission characteristics and also having a compact size by improving an arrangement structure of a circuit board.

2. Discussion of Related Art

In radio frequency (RF) communication, a frequency up converter is a device for upconverting a signal generated in a modem into a transmission frequency.

In satellite communication, heat is generated inside the frequency up converter for upconverting a frequency and increasing an output to a desired level.

In order to emit the heat inside the frequency up converter to the outside, a heat sink protruding to the outside in the top and bottom of the frequency up converter is installed.

The frequency up converter becomes bigger and heavier due to the heat sink located in both sides of the frequency up converter.

Accordingly, a development of technology capable of simultaneously solving a heat/size/weight problem in the frequency up converter is needed.

In this regard, Patent Reference 1 relates to technology capable of simply solving a heat emission problem of a high power device through a structural change of high frequency communication equipment (ODU), and includes a heat emission structure specific to a component in order to emit the heat of the component generating a large amount of heat like the high power device such as an amplifier, etc.

That is, as shown in FIG. 3, referring to Patent Reference 1, a circuit board is installed inside a body 200 in which a plurality of emission fins are formed, a shield ring 400 having an excellent heat conductivity in which a groove surrounding only a high power device 100h among components installed in the circuit board is formed, is installed and absorbs heat generated from the high power device 100h and emits the absorbed heat to the outside.

The conventional technology reduces a heat emission structure in a region which does not emit the heat by adding the heat emission structure specific to a device emitting a large amount of heat and slightly improves the heat emission characteristics in a region which emits a large amount of heat, but has limitations in miniaturization and weight minimizing due to a structure of emitting the heat to the top and bottom, that is, a structure in which the heat sink is installed in both of the top and bottom.

Further, there is a problem in which a waterproofing function is degraded since a fixing member for fixing an inner configuration penetrates a housing.

### SUMMARY OF THE INVENTION

The present invention is directed to a frequency up converter in which devices are separately arranged on boards formed in a multi-step structure by classifying the devices according to their heat generation rate, a heat emission effect is increased by installing a heat transmission medium between the boards, and also miniaturization and weight minimizing are achieved.

The present invention is further directed to a frequency up converter in which various electric or electronic devices constituting the frequency up converter are classified as a device having a relatively high heat generation rate and a device having a relatively low heat generation rate according to a heat generation rate, the classified devices are installed on a different boards, the boards are stacked in a multi-step structure, the heat generated in each board is effectively emitted by installing a heat transfer medium which is in contact with a heat sink between the boards, and thus heat emission efficiency is increased, miniaturization and weight minimizing are achieved.

According to an aspect of the present invention, there is provided a frequency up converter having a compact size and enhanced heat emission characteristics, including: a heat sink 10 installed on one side inside a housing 10h and configured to emit heat generated in the inside to the outside; a first circuit board 20 installed on one side of the heat sink, and on which a low heat generating device having relatively low heat emission characteristics is installed; a second circuit board 30 installed at one side of the first circuit board, and on which a high heat generating device having relatively higher heat emission characteristics than the first circuit board is installed; and a third circuit board 50 installed to be spaced apart by a predetermined distance from the top of the first board 20, on which a heat generating device having relatively lower heat emission characteristics than the second circuit board 30 and relatively higher heat emission characteristics than the first circuit board 20 is installed.

The frequency up converter may further include an inner cover configured to protect the first circuit board from heat generated in a power supply installed on the third circuit board, and the third circuit board 50 includes the power supply having a high heat generation rate installed on one surface facing the inner cover and a DC circuit and a element installed on another surface which does not face the inner cover.

The frequency up converter may further include: a heat transfer medium 60 configured between the inner cover and the power supply.

The inner cover 40 may be installed to surround the first board 20.

The heat generating device including a power transistor (PT) and an amplifier (AMP) may be installed on the second circuit board 30 installed on the heat sink at one side of the first circuit board.

The frequency up converter may further include a leakage prevention seal 70 installed between an inner wall of the housing 10h and the heat sink 10.

### BRIEF DESCRIPTION OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a structural diagram illustrating a frequency up converter having a compact size and enhanced heat emission characteristics according to one embodiment of the present invention;

FIG. 2 is a structural diagram illustrating a frequency up converter having a compact and enhanced heat emission characteristics according to another embodiment of the present invention; and

FIG. 3 is a structural diagram of a conventional frequency up converter.

### DETAILED DESCRIPTION OF EXEMPLARY EMBODIMENTS

The present invention may be variably modified and have various embodiments, specific embodiments are illustrated in accompanying drawings and will be described in the detailed description of exemplary embodiments. However, the exemplary embodiments described herein are not intended to limit the concept of the present invention, and should be understood as including every modification, equivalent, and alternative included in the spirit and scope of the present invention

Similar numerals refer to similar components in the accompanying drawings. In the description of the present invention, when it is determined that a detailed description of the related art makes the gist of the present invention obscure, the detailed description thereof will be omitted.

The present invention can achieve miniaturization by reducing an overall size by stacking and installing a plurality of boards in a multi-step structure, and can effectively emit heat by including a heat transfer means between the boards.

The frequency up converter having a compact size and enhanced heat emission characteristics may have features in which devices or components are installed on two or more circuit boards 20, 30, and 50 by classifying the devices or components constituting the frequency up converter, the circuit boards 20, 30, and 50 are stacked and installed, and a heat sink 10 for emitting heat generated in the circuit boards 20, 30, and 50 is included.

As shown in FIG. 1, the heat sink 10 may be installed on one side of a housing 10h and include a plurality of cooling fins formed on the outer surface of the heat sink 10, and thus effectively emit heat generated in the circuit boards 20, 30, and 50 installed inside.

Each of the circuit boards 20 and 30 among the circuit boards 20, 30, and 50 may be installed to be in close contact with an inner surface of the heat sink 10, and thus directly emit generated heat through the heat sink 10. The circuit board 50 may transfer the heat to the heat sink 10 through a heat transfer means.

The heat sink 10 may perform a function of emitting the heat generated from the circuit boards 20, 30, and 50 constituting the frequency up converter described above, and also a function of supporting the circuit boards 20, 30, and 50. The heat sink 10 may be made of a metal or ceramic, etc. having excellent heat conductivity.

The circuit boards 20, 30, and 50 may be a board on which a circuit including devices(the term “device” comprise “electrical element”) or components having different heat emission characteristics is installed, and be separately arranged by grouping devices or components having similar heat emission characteristics.

A first circuit board 20 among the circuit boards 20, 30, and 50 may be a board on which a low heat generating device having relatively low heat emission characteristics is installed, and may be installed adjacent to the heat sink 10 as shown in FIG. 1, and a second circuit board 30 on which devices having relatively high heat emission characteristics are installed may be installed at one side of the first circuit board 20. That is, a high heat generating device including a power transistor and an amplifier may be installed on the second circuit board 30 installed on the heat sink 10 at the one side of the first circuit board 20. At this time, the heat generating device including the power transistor and the amplifier may be installed on the bottom of the second circuit board 30, and emit the heat generated in the heat generating device through the heat sink 10 installed on the bottom of the second circuit board 30.

The second circuit board 30 may be a board on which a device or component having relatively higher heat emission characteristics than the devices constituting the first circuit board 20 is installed, and thus effectively emit heat inside the second circuit board 30 to the heat sink 10 by installing a cover 30c outside the second circuit board 30 and being in contact with the heat sink 10.

Further, the frequency up converter having a compact size and enhanced heat emission characteristics according to an embodiment of the present invention may install the devices and components on the third circuit board 50 by further classifying the heat emission characteristics of the devices or components.

The third circuit board 50 may be stacked and installed to be spaced apart by a predetermined interval on the top of the first circuit board 20.

The third circuit board 50 may be a board on which a circuit including a component or device having relatively higher heat emission characteristics than a component or device installed on the first circuit board 20, or components generating an unwanted spurious electronic wave is installed, and may include a power supply (PS) installed on one surface facing the first circuit board 20 and a direct current (DC) circuit and a DC device needed for driving control of the PS installed on another surface which does not face the first circuit board 20.

Other devices may not be influenced by the electronic wave generated in the devices constituting the third circuit board 50 by separating devices generating the unwanted electronic wave in the third circuit board 50.

An internal cover 40 may be included as a means for transferring heat generated in the high heat generating device or the PS installed on the third circuit board 50 to the heat sink 10.

That is, the devices installed on each circuit board constituting the frequency up converter having a compact size and enhanced heat emission characteristics may have a decreasing heat generation rate in order of the second circuit board, the third circuit board, and the first circuit board.

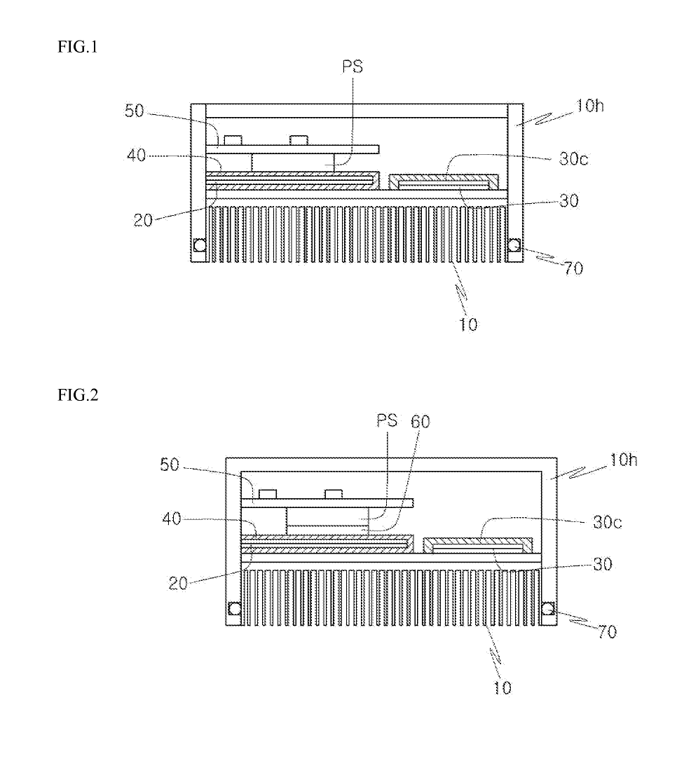

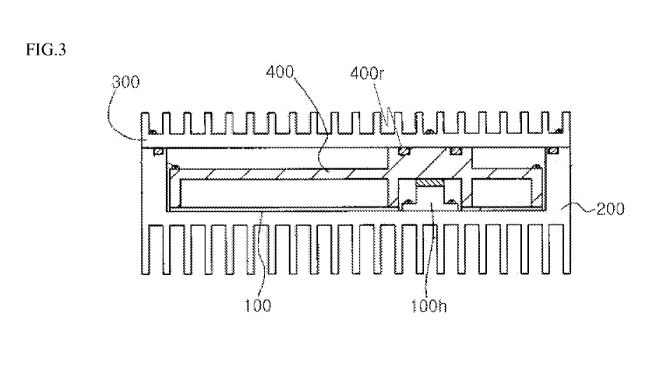

As shown in FIGS. 1 and 2, the inner cover 40 may have features in which one side is in contact with the heat sink 10, the first circuit board 20 is installed therein, heat generated in the high heat generating device or component of the third circuit board 50 is prevented from being transferred to the first circuit board 20, and the heat generated in the third circuit board 50 is effectively transferred to the heat sink 10. Accordingly, it may be desirable to manufacture the inner cover 40 using a material having excellent heat conductivity.

As described above, it may be desirable to further install a heat transfer medium 60 between the inner cover 40 and the PS in order to increase heat emission efficiency of emitting the heat of the third circuit board 50 transferred to the heat sink 10 through the inner cover 40, specifically, the heat generated in the PS.

Of course, the heat transfer medium 60 may be manufactured with a material having excellent heat conductivity, one side of the heat transfer medium 60 may be in contact with the PS, and another side of the heat transfer medium 60 may be in contact with the outer surface of the inner cover 40.

The heat transfer medium 60 may be a liquid type in which a liquid having high heat transfer efficiency is stored or a solid type pad having the high heat transfer efficiency.

As described above, the inner cover 40 may have a function of transferring the heat generated in the third circuit board 50 to the heat sink 10, and also a function of protecting the first circuit board 20 from the heat generated in the third circuit board 50. As shown in FIGS. 1 and 2, it may be desirable to design the inner cover 40 so that it surrounds the first circuit board 20.

A position of the third circuit board 50 may be exchanged with a position of the first circuit board 20 in order to easily emit the heat. However, when there is a space between the first circuit board 20 and peripheral media (a circuit board, a housing, etc.), the electronic wave generated in the first circuit board 20 may have an influence on an operation of a peripheral circuit. Accordingly, it may be desirable to manufacture the first circuit board 20 so that it is spaced apart from the peripheral circuit and is shielded by the inner cover 40. In this case, it may be desirable to manufacture the first circuit board 20 so that it is in close contact with the housing 10h in order to install easily in the shielding state.

Further, it may be desirable to design the housing 10h so that the frequency up converter having a compact size and enhanced heat emission characteristics according to an embodiment of the present invention prevents water from entering the housing 10h from the outside, and for this, it may be desirable to manufacture the housing 10h so that one side of the housing 10h has an open cylindrical shape and the inside of the housing is shielded by installing the heat sink 10 on the opened surface. Of course, the housing 10h can be manufactured so as to be divided and prevent leakage by further installing a leakage prevention packing at a portion connected to each other. Further, since the housing 10h is shielded by installing a leakage prevention seal 70 between an inner wall of the housing 10h and the heat sink 10, the water can be prevented from entering the housing 10h.

With the frequency up converter having a compact size and enhanced heat emission characteristics according to an embodiment of the present invention, as shown in FIGS. 1 and 2, enough heat emission can be achieved by installing the heat sink 10 on only one side, and water can be prevented from entering between an inside of the heat sink and the housing even when the heat sink is not installed on the top.

The frequency up converter having a compact size and enhanced heat emission characteristics of the present invention described above has features in which devices are installed on different boards by classifying the devices constituting the frequency up converter according to their heat generation rate, a board on which the relatively low heat generating device is installed is not influenced by the heat generated in the high heat generating device due to protection by a cover, and the heat emission efficiency is increased by effectively emitting the heat generated in the high heat generating device.

That is, since the heat generated from the high heat generating device or component does not pass through the low heat generating device and is emitted to the outside through the heat transfer medium-the cover-the heat sink, the heat generated from the high heat generating device cannot have an influence on another device, and can be effectively emitted.

Since the frequency up converter according to the present invention is constituted by stacking the plurality of boards, the frequency up converter can be constituted in a relatively small area compared with the conventional communication device, and thus can achieve miniaturization.

It will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A frequency up converter having a compact size and enhanced heat emission characteristics, comprising:
a heat sink (10) installed on one side inside a housing (10h) and configured to emit heat generated in the inside to the outside;
a first circuit board (20) installed on one side of the heat sink, and on which a low heat generating device having relatively low heat emission characteristics is installed;
a second circuit board (30) installed at one side of the first circuit board, and on which a high heat generating device having relatively higher heat emission characteristics than the first circuit board is installed; and
a third circuit board (50) installed to be spaced apart by a predetermined distance from the top of the first board (20), on which a heat generating device having relatively lower heat emission characteristics than the second circuit board (30) and relatively higher heat emission characteristics than the first circuit board (20) is installed.

2. The frequency up converter of claim 1, further comprising:
an inner cover configured to protect the first circuit board from heat generated in a power supply installed on the third circuit board,
wherein the third circuit board (50) comprises the power supply having a high heat generation rate installed on one surface facing the inner cover and a DC circuit and a device installed on another surface which does not face the inner cover.

3. The frequency up converter of claim 1, further comprising:
a heat transfer medium (60) configured between the inner cover and the power supply.

4. The frequency up converter of claim 1, wherein the inner cover (40) is installed to surround the first board (20).

5. The frequency up converter of claim 1, wherein a heat generating device including a power transistor (PT) and an amplifier (AMP) is installed on the second circuit board (30) installed on the heat sink at one side of the first circuit board.

6. The frequency up converter of claim 1, further comprising a leakage prevention seal (70) installed between an inner wall of the housing (10h) and the heat sink (10).
